(19) United States
(12) Patent Application Publication
(10) Pub. No.: US 2011/0158774 A1
(43) Pub. Date: Jun. 30, 2011

(54) SUBSTRATE PROCESSING APPARATUS AND METHOD

(75) Inventor: Hirofumi YAMAGUCHI, Nirasaki City (JP)

(73) Assignee: TOKYO ELECTRON LIMITED, Minato-ku (JP)

(21) Appl. No.: 12/977,444

(22) Filed: Dec. 23, 2010

(30) Foreign Application Priority Data
Dec. 24, 2009 (JP) 2009-293112

(51) Int. Cl. H01L 21/677

(52) U.S. Cl. 414/222.02

(57) ABSTRACT

A substrate processing apparatus includes mounting units for mounting transfer containers, a substrate transfer unit for unloading substrates from a transfer container, processing unit for processing the substrates from the transfer container, an image pickup unit for capturing at one time an image of the entire substrate accommodating region of the transfer container before the substrate transfer unit unloads the substrates from the transfer container and a moving unit for moving the image pickup unit horizontally along one direction. The apparatus further includes an information acquiring unit for acquiring information on vertical positions of the substrates based on the image obtained by the image pickup unit and a control unit for controlling the substrate transfer unit to unload the substrates accommodated in the transfer container based on the information on the vertical positions of the substrates. The image pickup unit is provided in common for at least two of the transfer containers.

### CROSS-REFERENCE TO RELATED APPLICATIONS

This application claims priority to Japanese Patent Application No. 2009-293112 filed on Dec. 24, 2009, the entire contents of which are incorporated herein by reference.

### FIELD OF THE INVENTION

The present invention relates to a substrate processing apparatus and method for unloading substrates from transfer containers and performing a process on the substrates.

### BACKGROUND OF THE INVENTION

As a substrate processing apparatus for manufacturing a semiconductor device, there has been known, for example, an apparatus for unloading a substrate such as a semiconductor wafer from a FOUP (transfer container) by using a transfer arm provided in a loader module and transferring the wafer to a processing unit for performing, e.g., a vacuum process, a resist coating process and the like thereon. The substrate processing apparatus is provided with horizontally arranged mounting units (loading ports) for respectively mounting (connecting) FOUPs.

Further, in order to detect whether or not there is a wafer in a FOUP and a vertical position of a wafer, for example, a mapping sensor having an optical sensor is provided at each of the FOUPs or the loading ports. However, a plurality of, e.g., two, wafers can be received in one slot by, e.g., a mistake of an operator, or one wafer may be slantingly received in two (upper and lower) slots (so-called cross-slotted). In the above cases, the detection results are mistakenly interpreted as detection errors the causes of which are attributed to an error in the thickness of the wafer, an error in an inclination of the FOUP and the like, so that it is sometimes difficult to detect the above-described cases. Further, each of the loading ports requires a sensor, thereby causing an increase in the cost. Further, since it is designed to decrease an area of the loader module as much as possible in order to reduce an installation area (footprint) of the apparatus, it is impossible to install a large sensor in the loader module (transfer arm).

Japanese Patent Application Publication Nos. 2005-64515 and 2005-520350 (corresponding to U.S. Patent Application Publication No. 2005/0035313 and International Patent Application Publication No. WO03/100725, respectively) disclose technology for detecting a position of a wafer in a FOUP by using a camera. Since, however, the camera only covers a small field of view, it is necessary, e.g., to vertically move or pan the camera in order to capture an image of an entire wafer accommodating region of the FOUP. Accordingly, it takes long time to capture an image, thereby reducing a throughput and complicating processing of the captured image.

Further, the camera has a long focal length and, thus, it is necessary to separate the camera from the FOUP by a large distance in order to locate the camera between the transfer arm and the FOUP, thereby increasing an installation area of the apparatus. Further, since a processing unit and a load-lock chamber for performing conversion of an atmosphere are provided at a side of the loader module opposite to a side thereof where the FOUP is arranged, it may cause an interference with a transfer operation of the transfer arm, which makes it difficult to provide the camera in the load-lock chamber or the processing unit.

### SUMMARY OF THE INVENTION

In view of the above, the present invention provides a substrate processing apparatus and method for unloading substrates from transfer containers mounted on mounting units arranged horizontally and performing a process on the substrates, the apparatus and the method capable of accurately obtaining vertical positions of the substrates in each of the transfer containers, and a storage medium storing the method.

In accordance with a first aspect of the present invention, there is provided a substrate processing apparatus including: mounting units for mounting thereon transfer containers arranged horizontally in one direction, each transfer container being configured to accommodate a plurality of substrates at different heights in a substrate accommodating region and having a loading/unloading opening for the substrates at a front side thereof; a substrate transfer unit for unloading substrates from a transfer container mounted on a mounting unit; one or more processing unit for processing the substrates unloaded by the substrate transfer unit; an image pickup unit for capturing at one time an image of the entire substrate accommodating region of the transfer container before the substrate transfer unit unloads the substrates from the transfer container; a moving unit for moving the image pickup unit horizontally along said one direction in a region including a position facing a front side of the transfer container mounted on the mounting unit; an information acquiring unit for acquiring information on vertical positions of the substrates based on the image obtained by the image pickup unit; and a control unit for controlling the substrate transfer unit to unload the substrates accommodated in the transfer container based on the information on the vertical positions of the substrates.

The image pickup unit is provided in common for at least two of the transfer containers.

In accordance with a second aspect of the present invention, there is provided a substrate processing method including: mounting transfer containers on mounting units horizontally in one direction, each transfer container being configured to accommodate a plurality of substrates at different heights in a substrate accommodating region and having a loading/unloading opening for the substrates at a front side thereof; capturing at one time a first image of the entire substrate accommodating region of a first target transfer container by an image pickup unit by moving the image pickup unit horizontally along said one direction in a region including a position facing a front side of the first transfer container mounted on a first mounting unit and stopping the image pickup unit at the position facing the front side of the first transfer container; acquiring information on vertical positions of substrates accommodated in the first transfer container based on the first image; retracting the image pickup unit from the position facing the front side of the first transfer container, and unloading the substrates from the first transfer container by a substrate transfer unit based on the information on the vertical positions of the substrates.

The method further includes capturing at one time a second image of the entire substrate accommodating region of a second transfer container by the image pickup unit by moving the image pickup unit horizontally along said one direction in a region including a position facing a front side of the second transfer container mounted on a second mounting unit and stopping the image pickup unit at the position facing the front side of the second transfer container; acquiring information on vertical positions of substrates accommodated in the second transfer container based on the second image; retracting the image pickup unit from the position facing the front side of the second transfer container, and unloading the substrates from the second transfer container by the substrate transfer unit based on the information on the vertical positions of the substrates in the second transfer container; and processing the substrates unloaded from the first and the second transfer container.

### BRIEF DESCRIPTION OF THE DRAWINGS

The objects and features of the present invention will become apparent from the following description of embodiments, given in conjunction with the accompanying drawings, in which:

FIG. 1 is a plan view showing an example of a substrate processing apparatus in accordance with an embodiment of the present invention;

FIG. 2 illustrates a side view showing a part of the substrate processing apparatus;

FIG. 3 schematically shows an inner region of a FOUP;

FIG. 4 is a front view of FOUPs connected to the substrate processing apparatus, which is seen from a transfer arm;

FIG. 5 illustrates a side view of an exemplary image pickup unit provided in the substrate processing apparatus;

FIG. 6 schematically shows an example of a controller of the substrate processing apparatus;

FIG. 7 is a flow chart showing an example of an operation of the substrate processing apparatus;

FIG. 8 is a flow chart showing an example of an operation of the substrate processing apparatus;

FIG. 9 schematically shows a state in which a FOUP is connected to the substrate processing apparatus;

FIGS. 10A and 10B are plan views, each showing an example of an operation in the substrate processing method;

FIGS. 11A and 11B schematically show an example of a FOUP on which mapping is performed in the substrate processing method;

FIG. 12 is a plan view showing an example of a substrate processing apparatus in accordance with another embodiment of the present invention;

FIG. 13 is a plan view showing an example of a substrate processing apparatus in accordance with still another embodiment of the present invention; and

FIG. 14 is a plan view showing an example of a substrate processing apparatus in accordance with still another embodiment of the present invention.

### DETAILED DESCRIPTION OF THE EMBODIMENTS

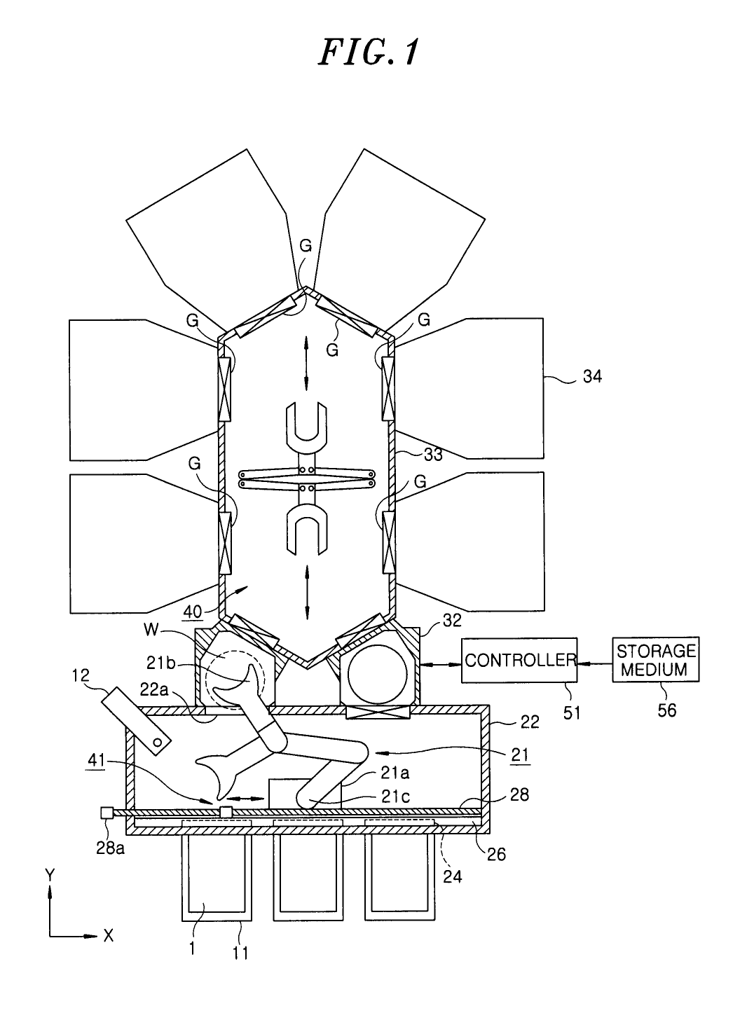

Embodiments of the present invention will be described with reference to FIGS. 1 to 6 which form a part hereof.

As shown in FIG. 1, a substrate processing apparatus includes mounting stages 11 (mounting units) for respectively mounting FOUPs 1 thereon that are transfer containers, each accommodating a plurality of, e.g., twenty-five, semiconductor wafers W serving as substrates, an atmospheric transfer chamber (loader module) 22 having a first transfer arm 21 serving as a substrate transfer unit for loading/unloading the wafers W into/from the FOUPs 1 mounted on the mounting stages 11, and processing units for performing a vacuum process such as heat treatment, plasma processing and the like on the wafers W unloaded from one of the FOUPs 1 by the first transfer arm 21.

Two load-lock chambers 32 for conversion between the atmospheric atmosphere and vacuum atmosphere are horizontally arranged to be connected to a rear sidewall (i.e., on the upper side in FIG. 1) of the atmospheric transfer chamber 22. Processing modules 34 including processing chambers as the processing units are airtightly connected to a vacuum transfer chamber 33 provided at sidewalls of the load-lock chambers 32 oppositely facing sidewalls thereof connected to the atmospheric transfer chamber 22. In this embodiment, a plurality of (e.g., six) processing modules 34 are provided. The vacuum transfer chamber 33 has two second transfer arms 40 for performing delivery of the wafers W between the processing modules 34 and the load-lock chambers 32. Delivery openings 22a through which the wafers W are transferred are formed at the sidewall of the atmospheric transfer chamber 22 connected to the load-lock chambers 32. Further, ‘G’ of FIG. 1 denotes a gate valve.

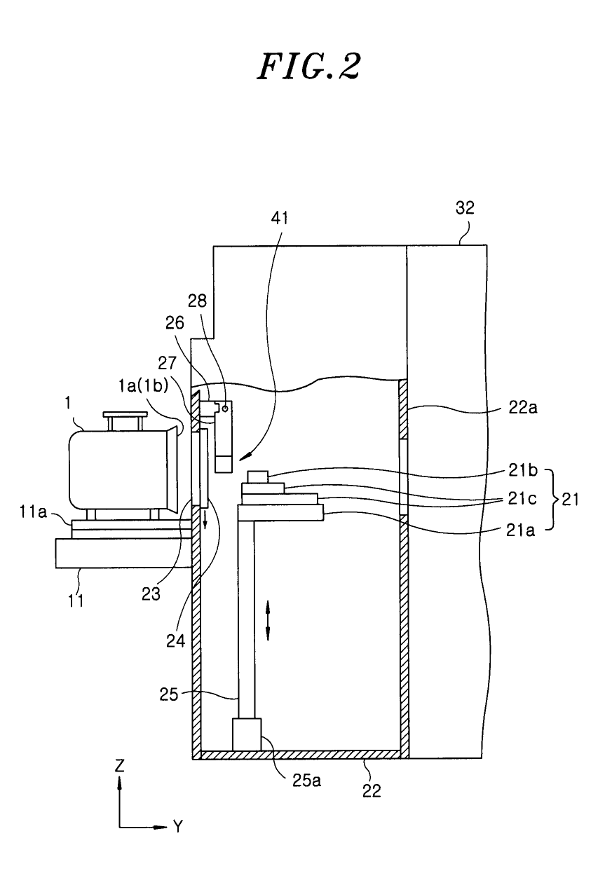

A plurality of (e.g., three) mounting stages 11 is arranged in a horizontal direction at a sidewall of the atmospheric transfer chamber 22, other than the sidewall connected to the load-lock chambers 32, i.e., a front sidewall (on the lower side in FIG. 1) in this example. Transfer ports 23 for transferring the wafers W between the FOUPs 1 and the atmospheric transfer chamber 22 are respectively formed at portions of the sidewall of the atmospheric transfer chamber 22 to which the mounting stages are arranged, as shown in FIG. 2. Further, a region where each of the three mounting stages 11 is arranged forms a loading port. As shown in FIGS. 1 and 2, openers 24 are provided in the atmospheric transfer chamber 22 to separate doors 1a provided at front sides of the FOUPs 1 from the FOUPs 1 while closing the transfer ports 23, respectively. In each case, when the FOUP 1 mounted on the mounting stage 11 (specifically, carrier stage 11a disposed on the mounting stage 11) is pulled toward the atmospheric transfer chamber 22 by the mounting stage 11 such that a loading/unloading opening 1b of the FOUP 1 is in contact with the transfer port 23, the door 1a is moved down together with the opener 24 which is moved down in the atmospheric transfer chamber 22 such that inner space of the FOUP 1 communicates with the inside of the atmospheric transfer chamber 22.

The first transfer arm 21 is vertically movably supported by an elevating support shaft 25 uprising from a bottom surface of the atmospheric transfer chamber 22 at an approximately central portion of the atmospheric transfer chamber 22 in its longitudinal direction (left-to-right direction (x-direction) in FIG. 1) as shown in FIGS. 1 and 2. The first transfer arm 21 moves up and down with respect to wafer mounting surfaces of the two load-lock chambers 32 and the FOUPs 1 mounted on the respective mounting stages 11 to perform delivery of the wafers W. Further, the first transfer arm 21 is configured as a multi-joint arm capable of transferring the wafers W to the load-lock chambers 32 and the FOUPs 1. The first transfer arm 21 includes a base body 21a connected to an upper end of the elevating support shaft 25, arms (e.g., two arms) 21b for supporting the wafers W from the bottom and transferring the wafers W, and two arm units 21c stacked between the base body 21a and the arms 21b for connection of their ends. Reference numeral ‘25a’ in FIG. 2 denotes an elevation unit for elevating the elevating support shaft 25.

Further, as shown in FIG. 1, an alignment mechanism 12 for adjusting orientations of the wafers W or modifying eccentricity of the wafers W is provided at a lateral side of the atmospheric transfer chamber 22. For example, the orientations of the wafers W are adjusted or the eccentricity of the wafers W is modified by the alignment mechanism 12 before the wafers W unloaded from any one of the FOUPs 1 are transferred to the load-lock chambers 32. Further, the first transfer arm 21 is schematically illustrated.

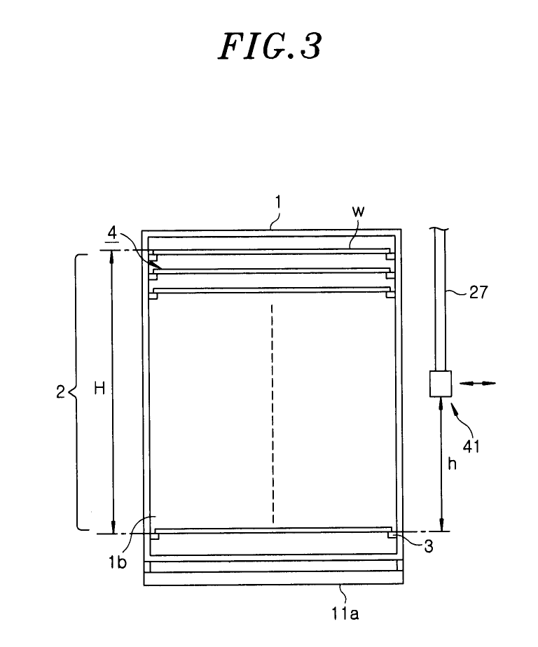

Next, an image pickup unit 41 provided in common to all of the FOUPs 1 mounted on the mounting stages 11 to detect vertical positions of the wafers W accommodated in each of the FOUPs 1 will be described. First, an inner structure of the FOUPs 1 will be explained in brief with reference to FIG. 3. Protrusions 3 supporting peripheral portions of the wafers W from the bottom are vertically provided in each of the FOUPs 1 at multiple levels along an inner surface of the corresponding FOUP 1.

When areas on which the wafers W are mounted on the protrusions 3 (substrate accommodating areas) are referred to as slots 4, a plurality of, e.g., twenty-five slots 4 are formed in each of the FOUPs 1 in a vertical direction. A distance (pitch) between adjacent wafers W is set to be, e.g., about 10 mm. Accordingly, a height dimension H of a accommodating region 2 accommodating the wafers W in each of the FOUPs 1 is, e.g., 250 mm.

A rail 26 serving as a guide portion horizontally extending along the arrangement direction of the three FOUPs 1 is provided above the transfer ports 23 in an inner surface of the front wall (on the left side in FIG. 2) of the atmospheric transfer chamber 22. As shown in FIG. 2, a support part 27 that is provided to engage with the rail 26 extends downward from the rail 26 at a position separated with a gap from the inner wall surface of the atmospheric transfer chamber 22 toward the inside (toward the load-lock chambers 32) such that the support part 27 can be moved in a longitudinal direction of the atmospheric transfer chamber (left-to-right direction (X-direction)) without interfering with the door 1a and the opener 24.

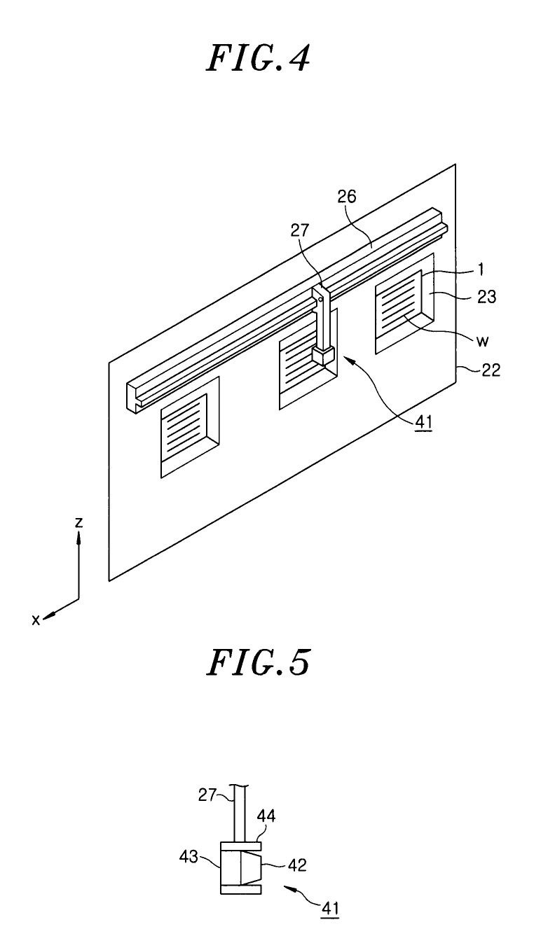

A ball screw 28 is provided in parallel to the corresponding rail 26 to pass through the support part 27 in the longitudinal direction of the atmospheric transfer chamber 22. The support part 27 can move along the rail 26 by screw connection between an outer peripheral surface of the ball screw 28 and an inner peripheral surface of the support part 27. A motor 28a for rotating the ball screw 28 around its axis is connected to one end of the ball screw 28 outside the atmospheric transfer chamber 22. A position of the support part 27 is obtained based on a rotation amount (encoder value) of the motor 28a. Further, illustration of the ball screw 28 and the first transfer arm 21 is omitted in FIG. 4.

The image pickup unit 41 provided at the support part 27 includes an imaging unit for capturing an image of the inside of each of the FOUPs 1. The imaging unit includes a CCD camera 42 and a wide angle lens 43 provided on the side of the transfer ports 23 at a side surface of the CCD camera 42. Further, the image pickup unit 41 includes a lighting unit 44 such as an LED for irradiating light onto an image pickup region (insides of the FOUPs 1) of the CCD camera 42, as shown in FIG. 5. Further, as shown in FIG. 3, a height dimension h of the image pickup unit 41 (length dimension of the support part 27) is set such that the image pickup unit 41 can move along the rail 26 at an appropriately vertically central position of the accommodating region 2 of each of the FOUPs 1 to allow the image pickup unit 41 to capture an entire image of the accommodating region 2 at a time. Further, the image data captured by the image pickup unit 41 are transmitted to a controller 51 which will be described later through a cable (not shown) or the like. Further, in this embodiment, the lighting unit 44 is attached to each of upper and lower sides of the wide angle lens 43.

The wide angle lens 43 is a lens having a product name of “Theia” manufactured by Nitto Optical Co., Ltd. (see U.S. Pat. No. 7,009,765). A moving path of the wide angle lens 43 along the rail 26 is close to the FOUPs 1 rather than a rotational center of the first transfer arm 21. Preferably, when the image pickup unit 41 captures an image of the inside of one of the FOUPs 1, the image pickup unit 41 does not interfere with the first transfer arm 21 performing delivery of the wafers W to the neighboring FOUP 1. This embodiment employs the wide angle lens 43 having an image capturing distance of 10 cm or less, which is a separation distance between an imaging target and a lens to capture an image of a region having, i.e., a size of 420 mm×297 mm. Accordingly, the rail 26 is arranged adjacent to the FOUPs 1.

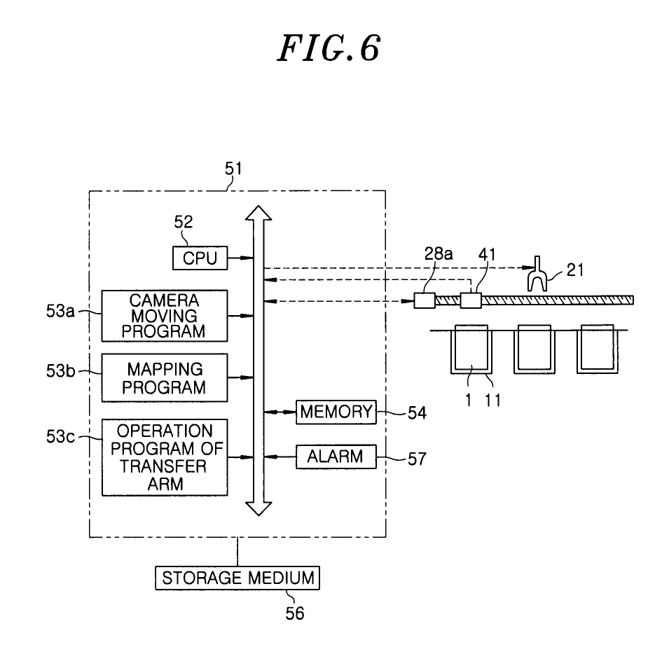

Further, as shown in FIG. 6, the substrate processing apparatus includes the controller 51 having a computer for controlling an entire operation of the apparatus. The controller 51 includes a CPU 52, a camera moving program 53a, a mapping program 53b, an operation program 53c of a transfer arm and a memory 54. Further, those programs are simply shown with reference numerals in FIG. 6 while the respective programs 53a, 53b and 53c are actually stored in a program storage unit.

The camera moving program 53a includes instructions to perform a step of detecting whether or not the door 1a of the FOUP 1 is opened, a step of detecting a destination of the CCD camera 42 and determining whether the first transfer arm 21 performs a transfer operation interfering with a moving path of the CCD camera 42 when the CCD camera 42 is ready to move to the destination, and a step of prohibiting a movement of the CCD camera 42, if the first transfer arm performs a transfer operation interfering with the movement of the CCD camera 42, until there is no interference between the CCD camera 42 and the first transfer arm 21.

Further, the mapping program 53b includes instructions to perform a mapping step of acquiring a vertical position of each wafer W and determining whether there is abnormality of a received state of the wafer W based on the image data obtained by the CCD camera 42. That is, since there is a fixed relationship between a vertical position of the CCD camera 42 and a vertical position of the mounting stages 11, it is possible to obtain a vertical position of each part of the image data obtained by the CCD camera 42 (in this embodiment, Z coordinate positions in a coordinate system for managing the position of the first transfer arm 21). Accordingly, the mapping program 53b detects a vertical position of each wafer W based on the image data obtained by the CCD camera 42 to store the detection results and, resultantly, it is also possible to determine presence and absence of a wafer W in each slot 4 in the FOUP 1 by obtaining a vertical position of the wafer W. Further, if the wafer W is abnormally received in the FOUP 1, for example, if several wafers W are received in one slot 4, or if a wafer W is slantingly received in two upper and lower slots 4, abnormality of a received state of the wafer W is detected based on the image data.

The operation program 53c of the first transfer arm 21 includes instructions to perform a step of prohibiting a transfer operation of the first transfer arm 21, if the first transfer arm 21 is about to perform a transfer operation interfering with a moving path of the CCD camera while the CCD camera 42 is moving, until there is no interference between the CCD camera 42 and the first transfer arm 21.

The memory 54 stores processing recipes including processing conditions for types of processing performed on each wafer W (e.g., a high frequency power to be applied, a flow rate of processing gas, a processing pressure, a processing time and the like in case of plasma processing), and information on vertical positions of wafers W of each FOUP 1 detected by the mapping program 53b. The above-described programs are installed in the controller 51 from a storage medium 56 such as a hard disc, a compact disc, a magneto-optical disc, a memory card, and a flexible disc.

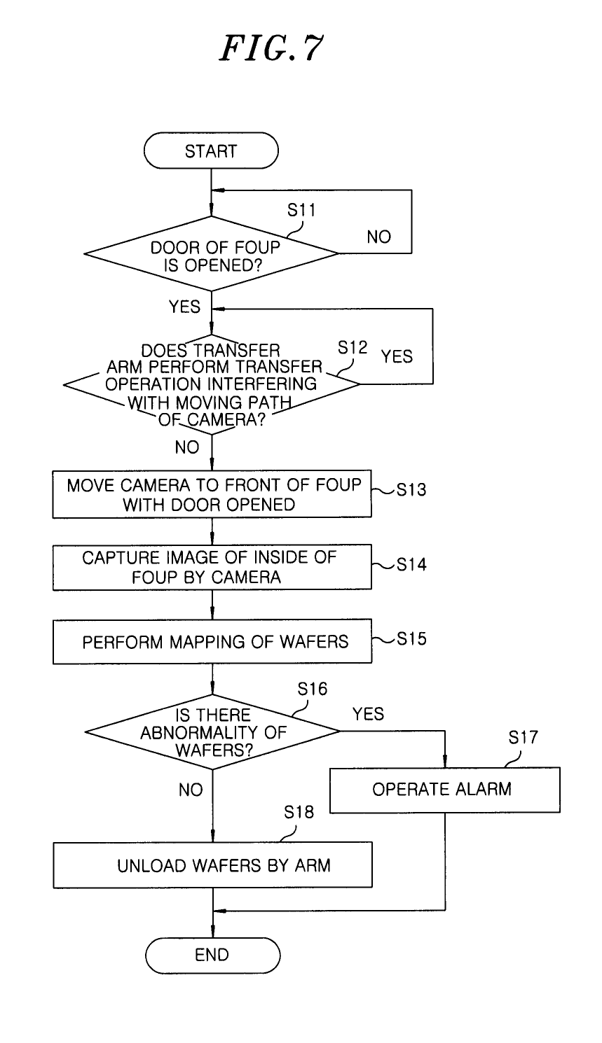

Next, a substrate processing method using the substrate processing apparatus in accordance with the embodiment of the present invention will be described with reference to FIGS. 7 to 11B.

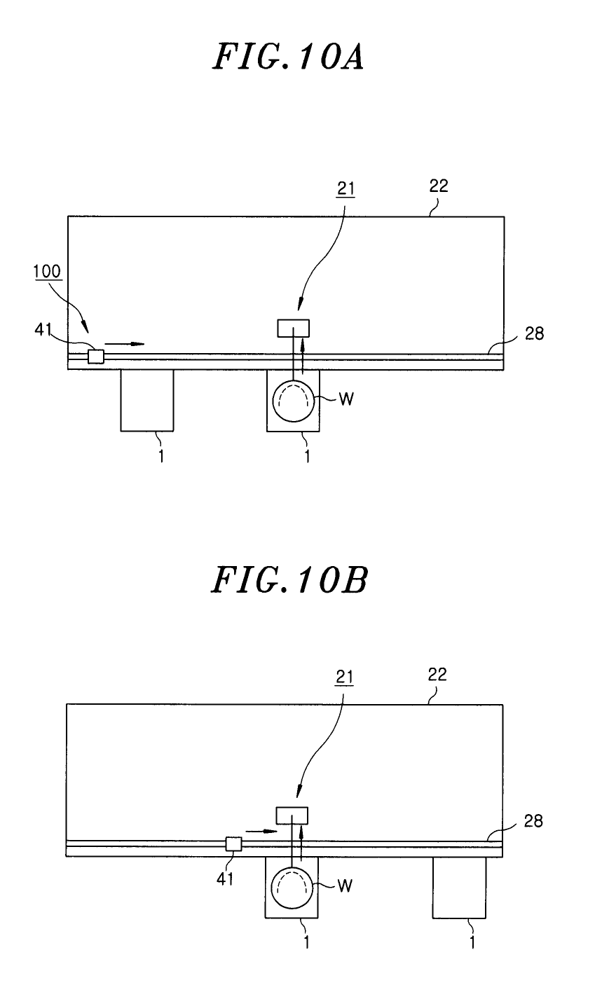

Suppose that at a current state, as shown in FIG. 10A, mapping for a FOUP 1 mounted on a central mounting stage 11 among three mounting stages 11 has been completed and wafers W have been unloaded from the FOUP 1 by the first transfer arm 21 and sequentially transferred to the load-lock chambers 32. Further, suppose that the image pickup unit 41 is in a standby mode in a loop of NO in step S11 at a standby position 100 positioned away from the arrangement of FOUPs 1. In FIGS. 10A and 10B, illustration of the processing units is omitted and the first transfer arm 21 and the like are schematically shown.

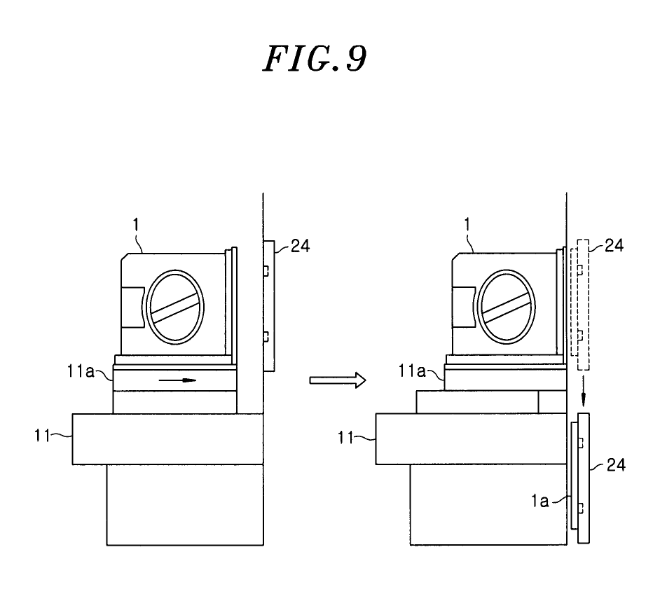

In the above state, for example, if a left FOUP 1 is mounted on a left mounting stage 11 and a door 1a thereof is opened as shown in FIG. 9, the determination in step S11 becomes YES and it is determined whether the first transfer arm 21 performs a transfer operation interfering with a moving path of the image pickup unit 41 from the standby position 100 to a destination that is a position facing the left FOUP 1 (step S12). As an example of a case in which the first transfer arm 21 performs a transfer operation interfering with a moving path of the image pickup unit 41, there is a case shown in FIG. 10 in which, for example, the first transfer arm 21 unloads wafers W from a central FOUP 1 mounted on the central mounting stage 11 among the three mounting stages 11 while the image pickup unit 41 moves from the standby position 100 toward a right FOUP 1 mounted on a right mounting stage 11 to capture an image of the inside of the right FOUP 1 across a region adjacent to the central FOUP 1. In this case, a movement of the image pickup unit 41 is prohibited until there is no interference between the image pickup unit 41 and the first transfer arm 21, that is, until a transfer operation of the first transfer arm 21 is completed.

Next, the image pickup unit 41 moves to a position facing the inside of a FOUP 1 with the door 1a opened (position facing the FOUP 1) (step S13), and the CCD camera 42 captures an image of the inside of the FOUP 1 (step S14). Then, as described above, mapping, i.e., detecting vertical positions of respective wafers W in the FOUP 1 is performed based on image data obtained by the CCD camera 42 (step S15), and it is determined whether each of the wafers W is normally (correctly) received (step S16). If abnormality of a received state of any one of the wafers W is detected, for example, an alarm 57 is operated (step S17), and the transfer operation of the first transfer arm 21 is stopped. In this case, for example, an operator may remove the FOUP 1 from the mounting stage 11 to check the inside of the FOUP 1.

Subsequently, the image pickup unit 41 is returned to the standby position 100. Although the operation is simplified in a flow chart shown in FIG. 7, similar operation as in step S12 is also carried out if the moving path of the image pickup unit 41 interferes with the transfer operation of the first transfer arm 21, that is, the movement of the image pickup unit 41 is prohibited until the transfer operation is completed. Further, if no abnormality in a received state of any one of the wafers W is detected based on the mapping results, an unloading operation of the wafers W is performed by the first transfer arm 21 (step S18).

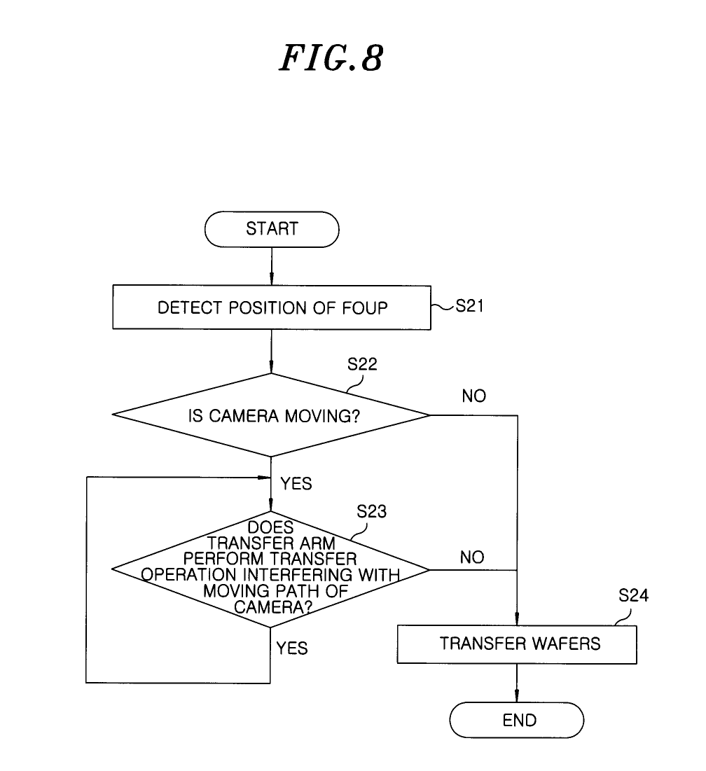

FIG. 8 is a flow chart for explaining the operation in the step S18. The position of a FOUP 1 from which the wafers W are unloaded is detected first (step S21), and it is determined whether the image pickup unit 41 is moving (step S22). If it is determined that the image pickup unit 41 is moving, then it is determined whether a moving path of the image pickup unit 41 interferes with a transfer operation of the first transfer arm 21 (step S23). Further, if there is an interference, the first transfer arm 21 waits in the standby mode until the movement of the image pickup unit 41 is completed and, then, the wafers W are unloaded from the FOUP 1 by the first transfer arm 21. Specifically, the first transfer arm 21 makes an access to the FOUP 1 on which new mapping has been performed under a predetermined rule and the wafers W are unloaded from the FOUP 1 based on information regarding vertical positions of the wafers W by referring to the memory 54, wherein the first transfer arm is adopted to perform the transfer of the wafers W between FOUPs 1, the alignment mechanism 12 and the load-lock chambers 32 in accordance with the predetermined rule. The unloading operation of the wafers W is performed by inserting the arm 21b into the FOUP 1 based on the information regarding vertical positions of the wafers W to lift the wafer W up and retracting the arm 21b (step S24).

Next, the wafer W is loaded into the processing module 34 through the alignment mechanism 12, the load-lock chambers 32 and the vacuum transfer chamber 33. By repeating this operation, the wafers W in the FOUP 1 are sequentially loaded into the processing modules 34 and the wafers W which have been processed are also sequentially returned to the FOUP 1.

In accordance with the embodiment of the present invention, the image pickup unit 41 which is horizontally movable along the arrangement of FOUPs 1 is positioned to face the loading/unloading opening 1b of one of the FOUPs 1 before unloading of wafers W from the corresponding FOUP 1 is performed by the first transfer arm 21. Then, the image pickup unit 41 captures an image of all slots 4 in the FOUP 1 simultaneously to obtain information regarding vertical positions of the wafers W based on the image data. Accordingly, it is possible to accurately obtain vertical positions of the wafers W in each of the FOUPs 1 and improve a throughput compared to, e.g., a case in which a common sensor is provided in the first transfer arm 21.

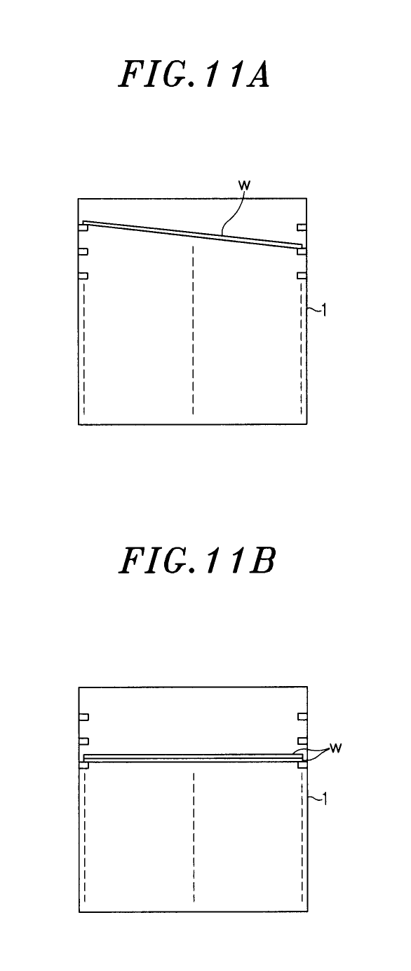

For example, as shown in FIGS. 11A and 11B, one wafer W may be slantingly received in two (upper and lower) slots 4 (so-called cross-slotted) by, e.g., a mistake of an operator, or a plurality of, e.g., two, wafers W may be received in one slot 4. Further, a vertical position of each slot 4 in a FOUP 1 may be tilted (deformed) over time. Even in these cases, an image of the accommodating region 2 of the wafers W is directly captured regardless of blocking or transmission of infrared rays, and it is possible to easily determine these abnormalities. Accordingly, it is possible to avoid a problem such as a reception error of a wafer W and collision with a wafer W, which may occur when the first transfer arm 21 (arm 21b) unloads the wafers W from the FOUP 1.

Further, since the wide angle lens 43 capable of capturing an image of the accommodating region 2 at a time is used, there is no need for a mechanism for vertically moving or panning a camera capable of only capturing an image of a small region. Further, since it takes short period of time to capture an image, it facilitates processing of the image data. Further, since the wide angle lens 43 causes a smaller distortion at an edge portion of the image as compared to, e.g., a fish-eye lens, it is possible to accurately obtain a vertical position of the wafer W.

Further, the CCD camera 42 can capture an image of a target (the accommodating region 2 of one of the FOUPs 1) at a position close to the target, e.g., at a distance of 10 cm or less from target. Accordingly, it is possible to suppress a reduction of throughput without interfering with the first transfer arm 21 performing a transfer operation on another FOUP 1.

Further, the FOUPs 1 share the image pickup unit 41. Accordingly, it is possible to achieve the cost reduction compared to a case in which a mapping sensor is provided in each of the FOUPs 1 or the mounting stages 11.

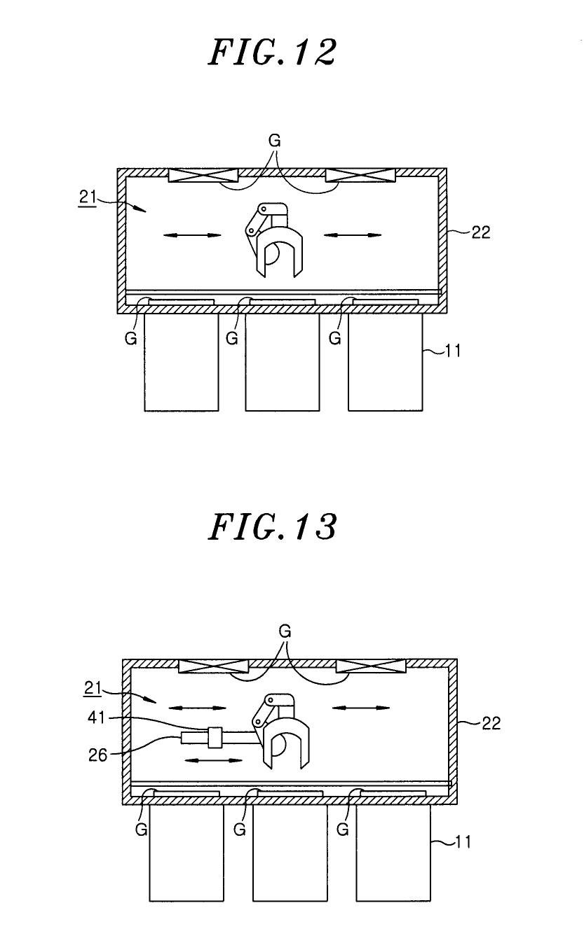

In this embodiment, the first transfer arm 21 is configured as a rotatable and expansible/contractible multi-joint arm capable of making an access to the three FOUPs 1, the alignment mechanism 12 and the two load-lock chambers 32. However, for example, a rotatable and expansible/contractible arm 21b may be provided on a base body 21a movable in a longitudinal direction (left-to-right direction (X-direction) in FIG. 1) of the atmospheric transfer chamber 22 so that the base body 21a can move to the front of each of the FOUPs 1 to make an access thereto, as shown in FIG. 12. In this case, as shown in FIG. 13, the rail 26 serving as a guide portion of the image pickup unit may be provided at the base body 21a of the first transfer arm 21 to shorten a length dimension of the rail 26 by using a moving stroke of the first transfer arm 21. Further, the illustration of the processing unit is omitted in FIGS. 12 and 13.

Further, although the image pickup unit 41 is used in common for the three mounting stages 11 in this embodiment, the image pickup unit 41 may be used in common for two mounting stages among the three mounting stages 11 and an additional image pickup unit 41 may be separately provided with respect to the remaining mounting stage 11.

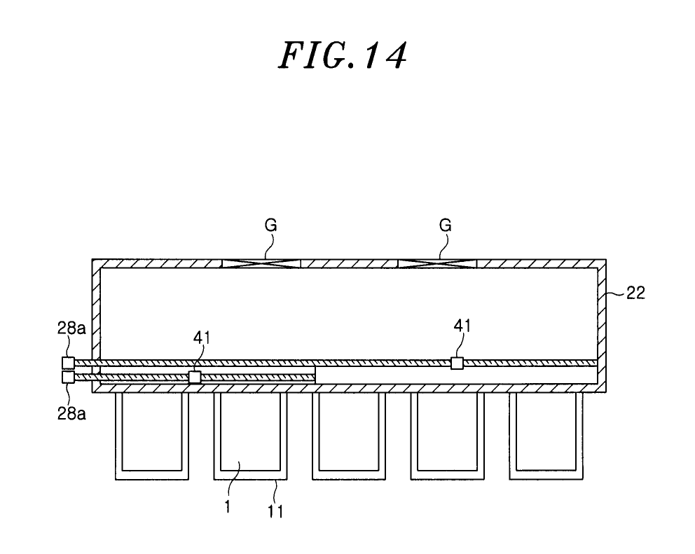

Further, in a case where at least three (e.g., five) mounting stages 11 are connected to the atmospheric transfer chamber 22, the image pickup unit 41 may be provided in common for all the mounting stages 11. Alternatively, for example, as shown in FIG. 14, an image pickup unit 41 may be provided in common for at least two (e.g., three) mounting stages 11 and an additional image pickup unit 41 may be provided in common for the other two mounting stages 11. In this case, each of the two image pickup units 41 may perform an image pickup operation on the mounting stages 11 assigned thereto. Alternatively, each of the two image pickup units 41 may independently perform an image pickup operation on the accommodating regions 2 of all the mounting stages 11. In other words, an image pickup unit 41 may be provided in common to two mounting stages 11 located on the right side among five mounting stages 11 horizontally arranged right in front of the atmospheric transfer chamber 22 and an additional image pickup unit 41 may be provided in common to three mounting stages 11 located on the left side. Alternatively, respective rails 26 of two image pickup units 41 may be provided from the mounting stage 11 on the right side to the mounting stage 11 on the left side, so that each of the image pickup units 41 can capture an image of the inside of the FOUP 1 on each of the five mounting stages 11.

Although the FOUPs 1 are connected to the outside of the substrate processing apparatus in the above embodiment, the present invention may be applied to, e.g., a vertical heat treatment apparatus in which the FOUPs 1 are sequentially loaded in the apparatus, wafers W are unloaded from each of the FOUPs 1 in order, and each of the FOUPs 1 is stored in the apparatus. Further, a substrate processing in the embodiment of the present invention includes inspection of external appearance or circuits formed on the wafers W. Further, although the substrate processing apparatus serving as a multi-chamber module having processing modules 34 has been described in the above embodiment, the present invention may be applied to, e.g., a coating and developing apparatus. Further, although a sealed FOUP 1 has been described as an example of a accommodating container accommodating wafers W in the above embodiment, a so-called open type cassette (carrier) having a cover on its front surface may be used as a transfer container.

In accordance with the embodiment of the present invention, the image pickup unit which is horizontally movable along the arrangement of the transfer containers is positioned to face an opening of each of the transfer container before the substrates are unloaded from the corresponding transfer container by the substrate transfer unit. Then, the image pickup unit captures an image of an entire substrate accommodating region in each of the transfer container at a time to obtain vertical position information of the substrates based on the image data. Accordingly, it is possible to accurately obtain vertical positions of the substrates in each of the transfer container and improve a throughput compared to, e.g., a case in which a common sensor is provided in the substrate transfer unit.

While the invention has been shown and described with respect to the embodiments, it will be understood by those skilled in the art that various changes and modification may be made without departing from the scope of the invention as defined in the following claims.

What is claimed is:

1. A substrate processing apparatus comprising:
mounting units for mounting thereon transfer containers arranged horizontally in one direction, each transfer container being configured to accommodate a plurality of substrates at different heights in a substrate accommodating region and having a loading/unloading opening for the substrates at a front side thereof;
a substrate transfer unit for unloading substrates from a transfer container mounted on a mounting unit;
one or more processing unit for processing the substrates unloaded by the substrate transfer unit;
an image pickup unit for capturing at one time an image of the entire substrate accommodating region of the transfer container before the substrate transfer unit unloads the substrates from the transfer container;
a moving unit for moving the image pickup unit horizontally along said one direction in a region including a position facing a front side of the transfer container mounted on the mounting unit;
an information acquiring unit for acquiring information on vertical positions of the substrates based on the image obtained by the image pickup unit; and
a control unit for controlling the substrate transfer unit to unload the substrates accommodated in the transfer container based on the information on the vertical positions of the substrates,
wherein the image pickup unit is provided in common for at least two of the transfer containers.

2. The substrate processing apparatus of claim 1, wherein the image pickup unit includes a wide angle lens.

3. The substrate processing apparatus of claim 2, wherein the separation distances between the substrates accommodated in the transfer container and the image pickup unit are equal to or less than 10 cm.

4. The substrate processing apparatus of claim 1, further comprising a lighting unit which is moved together with the image pickup unit by the moving unit and irradiates light into the transfer container.

5. The substrate processing apparatus of claim 2, further comprising a lighting unit which is moved together with the image pickup unit by the moving unit and irradiates light into the transfer container.

6. The substrate processing apparatus of claim 3, further comprising a lighting unit which is moved together with the image pickup unit by the moving unit and irradiates light into the transfer container.

7. A substrate processing method comprising:
mounting transfer containers on mounting units horizontally in one direction, each transfer container being configured to accommodate a plurality of substrates at different heights in a substrate accommodating region and having a loading/unloading opening for the substrates at a front side thereof;
capturing at one time a first image of the entire substrate accommodating region of a first transfer container by an image pickup unit by moving the image pickup unit horizontally along said one direction in a region including a position facing a front side of the first transfer container mounted on a first mounting unit and stopping the image pickup unit at the position facing the front side of the first transfer container;
acquiring information on vertical positions of substrates accommodated in the first transfer container based on the first image;
retracting the image pickup unit from the position facing the front side of the first transfer container, and unloading the substrates from the first transfer container by a substrate transfer unit based on the information on the vertical positions of the substrates;
capturing at one time a second image of the entire substrate accommodating region of a second transfer container by the image pickup unit by moving the image pickup unit horizontally along said one direction in a region including a position facing a front side of the second transfer container mounted on a second mounting unit and stopping the image pickup unit at the position facing the front side of the second transfer container;
acquiring information on vertical positions of substrates accommodated in the second transfer container based on the second image;
retracting the image pickup unit from the position facing the front side of the second transfer container, and unloading the substrates from the second transfer container by the substrate transfer unit based on the information on the vertical positions of the substrates in the second transfer container; and
processing the substrates unloaded from the first and the second transfer container.

8. The substrate processing method of claim 7, wherein a wide angle lens is used in capturing the images of the entire substrate accommodating regions of the first and the second transfer container.

9. The substrate processing method of claim 8, wherein the separation distances between the substrates accommodated in the first and the second transfer container and the image pickup unit are equal to or less than 10 cm in capturing the images of the entire substrate accommodating regions of the first and the second transfer container.

10. The substrate processing method of claim 7, wherein light is irradiated in the first and the second transfer container in capturing the images of the entire substrate accommodating regions of the first and the second transfer container.

11. The substrate processing method of claim 8, wherein light is irradiated in the first and the second transfer container in capturing the images of the entire substrate accommodating regions of the first and the second transfer container.

12. The substrate processing method of claim 9, wherein light is irradiated in the first and the second transfer container in capturing the images of the entire substrate accommodating regions of the first and the second transfer container.
